(19) United States
(12) Patent Application Publication
(10) Pub. No.: US 2025/0109972 A1
(43) Pub. Date: Apr. 3, 2025

(54) SENSOR PACKAGE AND SENSING MODULE THEREOF

(71) Applicants: LITE-ON SINGAPORE PTE. LTD., Singapore (SG); LITE-ON TECHNOLOGY CORPORATION, TAIPEI CITY (TW)

(72) Inventors: GUANG-LI SONG, SINGAPORE (SG); WUI-PIN LEE, Singapore (SG); SIN-HENG LIM, SINGAPORE (SG); HENG-CHANG CHEN, New Taipei City (TW)

(21) Appl. No.: 18/900,953

(22) Filed: Sep. 30, 2024

(30) Foreign Application Priority Data
Oct. 2, 2023 (SG) 10202302819Y
Sep. 23, 2024 (CN) 202411321238.4

(51) Int. Cl. G01D 11/26; B81B 7/00

(52) U.S. Cl. CPC G01D 11/26; B81B 7/0048; B81B 7/0074; B81B 2207/07; B81B 2207/092

(57) ABSTRACT

A sensing module of a sensor package includes a substrate and a sensor. The substrate includes an insulating layer, an integrated circuit (IC), a plurality of first circuits, and a plurality of second circuits. The IC is embedded in the insulating layer and includes a plurality of first contacts and a plurality of second contacts. The first circuits are respectively connected to the first contacts, and a part of each of the first circuits is exposed from the first surface of the insulating layer and is defined as a connection pad. The second circuits are respectively connected to the second contacts, and a part of each of the second circuits is exposed from the second surface of the insulating layer and is defined as a soldering pad. The sensor is disposed on the first surface of the insulating layer and is electrically coupled to the first circuits.

### CROSS-REFERENCE TO RELATED PATENT APPLICATION

This application claims the benefit of priority to China Patent Application No. 202411321238.4, filed on Sep. 23, 2024, in the People's Republic of China. The entire content of the above identified application is incorporated herein by reference.

This application claims the benefit of priority to the Singapore Provisional Patent Application Ser. No. 10202302819Y, filed on Oct. 2, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package and a sensing module thereof.

### BACKGROUND OF THE DISCLOSURE

A sensor and a small single block or chip of a semiconductor known as an integrated circuit (IC) in a conventional sensor package are mounted side-by-side on a circuit board, thereby causing the conventional sensor package to have a large volume. Moreover, a portion of the circuit board between the sensor and the IC is easily affected by temperature (such as from operation thereof), which can lead to a warpage issue and a stress concentration issue.

### SUMMARY OF THE DISCLOSURE

In response to the above-referenced technical inadequacies, the present disclosure provides a sensor package and a sensing module thereof for effectively improving on the issues associated with conventional sensor packages.

In order to solve the above-mentioned problems, one of the technical aspects adopted by the present disclosure is to provide a sensing module of a sensor package structure, which includes a substrate and a sensor. The substrate includes an insulating layer, a processor, a plurality of first circuits, and a plurality of second circuits. The insulating layer has a first surface and a second surface that is opposite to the first surface. The IC is embedded in the insulating layer, and a top surface of the processor includes a plurality of first contacts and a plurality of second contacts. The first circuits are respectively connected to the first contacts, and a part of each of the first circuits is exposed from the first surface of the insulating layer and is defined as a connection pad. The second circuits are respectively connected to the second contacts, and a part of each of the second circuits is exposed from the second surface of the insulating layer and is defined as a soldering pad. The sensor is disposed on the first surface of the insulating layer and is electrically coupled to the first circuits.

In order to solve the above-mentioned problems, another one of the technical aspects adopted by the present disclosure is to provide a sensor package combined the sensing module and a sealing member such as sealing layer or sealing cover, to define an enclosed space, and the sensor is located in the enclosed space. Furthermore, the sealing member includes a light-permeable portion and a ring-shaped portion that surrounds the light-permeable portion.

Therefore, the sensor package and the sensing module provided by the present disclosure can effectively reduce an overall size thereof through a top-bottom arrangement of the sensor and the IC, and the insulating layer of the sensing module is used to be cooperated with the first circuits and the second circuits for replacing a conventional circuit board, thereby effectively preventing problems associated with the conventional circuit board.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package according to a first embodiment of the present disclosure;

FIG. 2 is a schematic exploded view of FIG. 1;

FIG. 3 is a schematic exploded view of a substrate of FIG. 2;

FIG. 4 is a schematic cross-sectional view taken along line IV-IV of FIG. 1;

FIG. 5 is a schematic cross-sectional view taken along line V-V of FIG. 1;

FIG. 6 is a schematic perspective view of the sensor package according to a second embodiment of the present disclosure;

FIG. 7 is a schematic exploded view of FIG. 6;

FIG. 8 is a schematic exploded view of the substrate of FIG. 7;

FIG. 9 is a schematic cross-sectional view taken along line IX-IX of FIG. 6; and

FIG. 10 is a schematic enlarged view of part X of FIG. 9.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

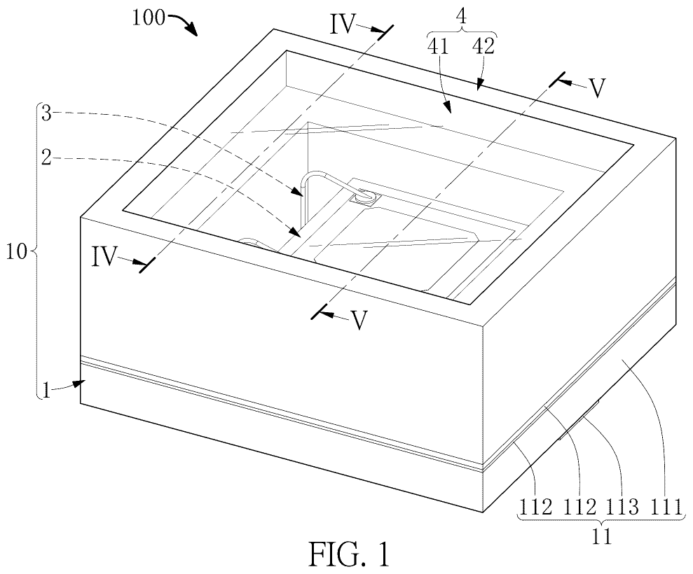

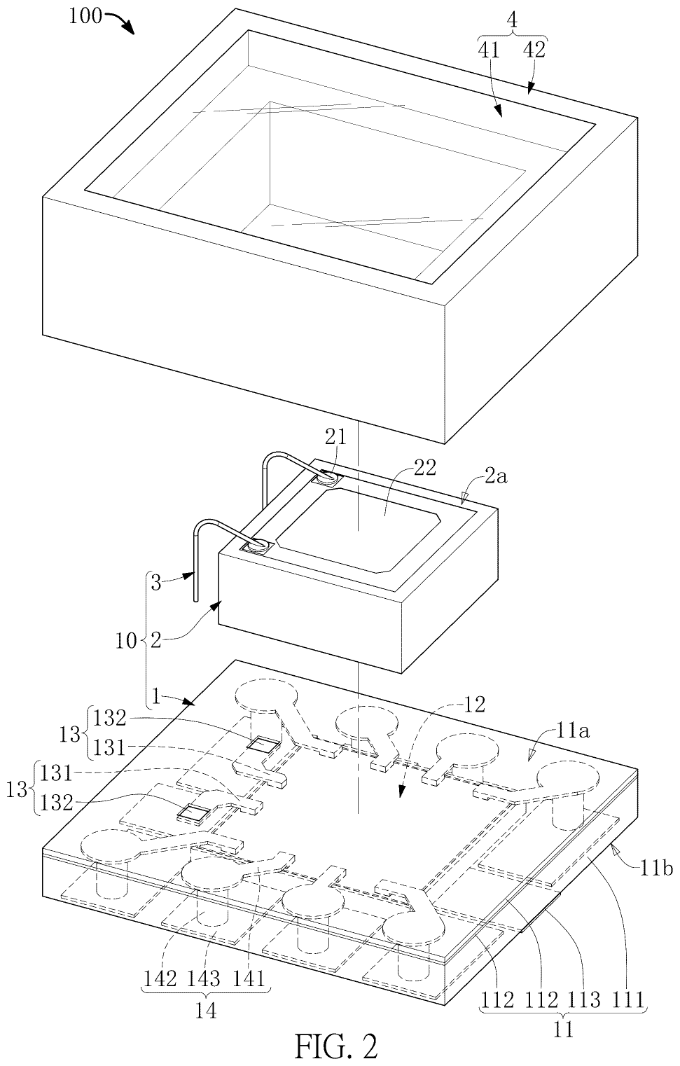

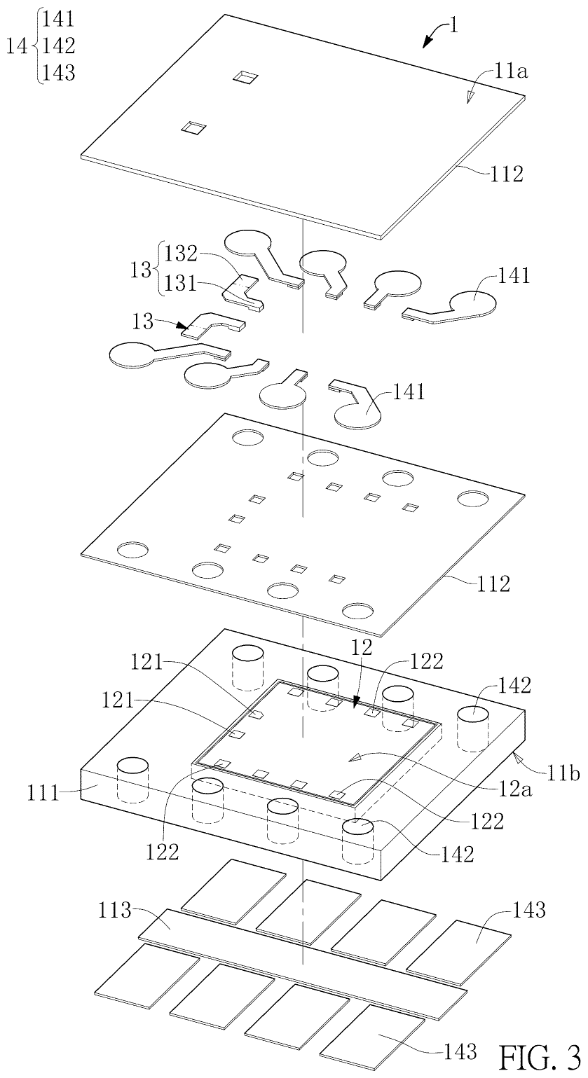

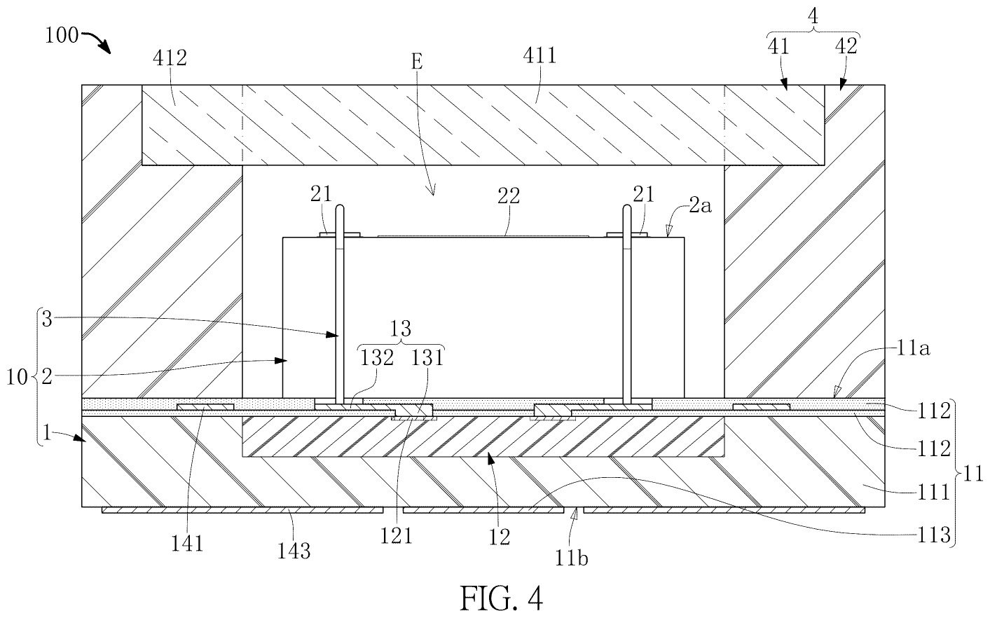

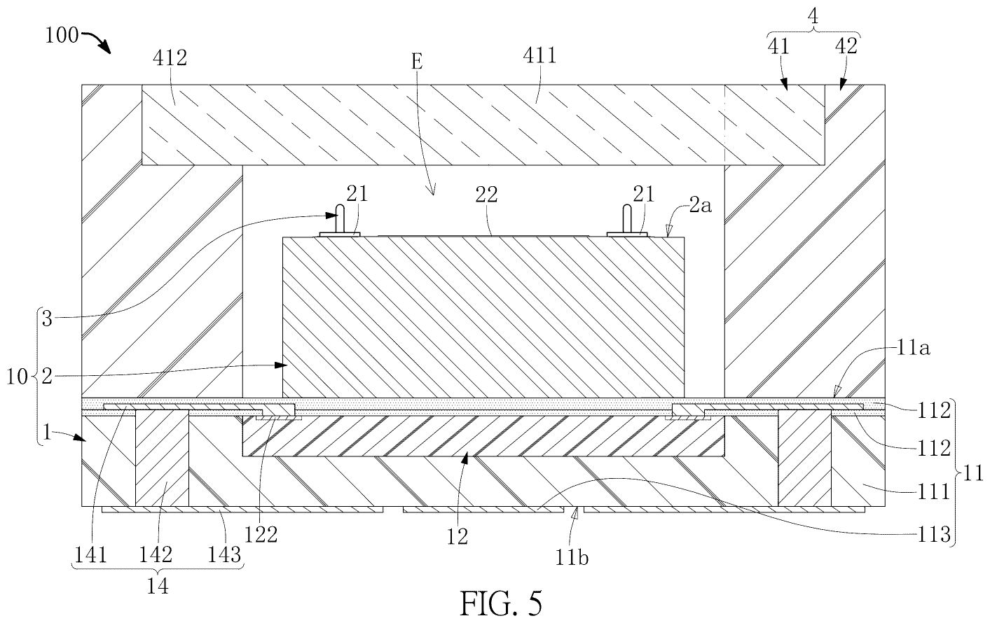

Referring to FIG. 1 to FIG. 5, a first embodiment of the present disclosure provides a sensor package 100, which includes a substrate 1, a sensor 2 disposed on the substrate 1, and a sealing cover 4 that is fixed to the substrate 1.

It should be noted that the substrate 1 and the sensor 2 in the present embodiment can be jointly defined as a sensing module 10, and the sensing module can further include components (e.g., metal wires 3) that are configured to be electrically coupled to the substrate 1 and the sensor 2. Moreover, the sensing module 10 in the present embodiment is in cooperation with the sealing cover 4, but the present disclosure is not limited thereto. For example, in other embodiments of the present disclosure not shown in the drawings, the sensing module 10 can be independently used or can be used in cooperation with other components according to practical requirements.

In the present embodiment, the substrate 1 includes an insulating layer 11, an IC 12 embedded in the insulating layer 11, a plurality of first circuits 13 electrically coupled to the IC 12, and a plurality of second circuits 14 that are electrically coupled to the IC 12. In addition, the IC 12 can be an application specific integrated circuit (ASIC) chip, but the present disclosure is not limited thereto.

Specifically, a top surface 12a of the IC 12 includes a plurality of first contacts 121 and a plurality of second contacts 122, and an outer surface of the insulating layer 11 has a first surface 11a and a second surface 11b that is opposite to the first surface 11a. The first circuits 13 are respectively connected to the first contacts 121, and each of the first circuits 13 includes a first fan-out segment 131 connected to the corresponding first contact 121 and a connection pad 132 that is connected to the first fan-out segment 131 and that is exposed from the first surface 11a. Moreover, the second circuits 14 are respectively connected to the second contacts 122, and each of the second circuits 14 includes a second fan-out segment 141 connected to the corresponding second contact 122, a conductive pillar 142 connected to the second fan-out segment 141, and a soldering pad 143 that is connected to the conductive pillar 142 and that is exposed from the second surface 11b. The first fan-out segments 131 of the first circuits 13 and the second fan-out segments 141 and the conductive pillars 142 of the second circuits 14 are embedded in the insulating layer 11.

Specifically, the insulating layer 11 in the present embodiment includes an encapsulant 111, two protective layers 112 disposed on one side of the encapsulant 111, and a protective strip 113 that is disposed on another side of the encapsulant 111. The IC 12 and the conductive pillars 142 of the second circuits 14 are embedded in the encapsulant 111, the top surface 12a of the IC 12 is partially or entirely exposed from the encapsulant 111, and two ends of each of the conductive pillars 142 are exposed from the encapsulant 111.

Furthermore, the encapsulant 111 is an epoxy molding compound (EMC) or a silicone molding compound (SMC) and has a coefficient of thermal expansion (CTE) of substantially 7 ppm/° C., thereby effectively protecting the IC 12.

Moreover, the two protective layers 112 are stacked on and cover the top surface 12a of the IC 12 and one of the two ends of each of the conductive pillars 142. The first fan-out segments 131 of the first circuits 13 and the second fan-out segments 141 of the second circuits 14 are embedded in the two protective layers 112, and the connection pads 132 of the first circuits 13 are exposed from one of the two protective layers 112. In addition, parts of the second fan-out segments 141 of the second circuits 14 are exposed from another one of the two protective layers 112 and individually connected to the corresponding conductive pillars 142 and the soldering pads 143 of the second circuits 14 both arranged in two rows, and the protective strip 113 is arranged between the two rows of the soldering pads 143.

In other words, each of the first circuits 13 extends from the corresponding first contact 121 to form the connection pad 132 on the first surface 11a of the insulating layer 11 by passing through the two protective layers 112. Each of the second circuits 14 extends from the corresponding second contact 122 to form the soldering pad 143 on the second surface 11b of the insulating layer 11 by passing through the two protective layers 112 and the encapsulant 111.

The sensor 2 in the present embodiment is a micro electro mechanical systems (MEMS) sensor, but the present disclosure is not limited thereto. The sensor 2 is disposed on the first surface 11a of the insulating layer 11 (i.e., the sensor 2 is disposed on the two protective layers 112), and the sensor 2 is electrically coupled to the first circuits 13.

In the present embodiment, an upper surface 2a of the sensor 2 includes a plurality of contacts 21, one end of the metal wires 3 is connected to the contacts 21 of the sensor 2, and another end of the metal wires 3 is connected to the connection pads 132 of the first circuits 13, so that the sensor 2 can be electrically coupled to the IC 12 through the metal wires 3 and the first circuits 13. Alternatively, an electrical connection between the substrate 1 and the sensor 2 can be established through other manners, such as to allow the metal wires 3 to be omitted.

In summary, the sensing module 10 of the present embodiment is a chip-scale configuration, thereby shortening an electrical transmission path between the sensor 2 and the IC 12 and reducing generation of inductance and noise. Moreover, the sensing module 10 is provided with the two protective layers 112 for separating the first circuits 13 and the second circuits 14 from the IC 12 and for effectively absorbing or releasing thermal stress that is generated by differences among a CTE of the sensor 2, a CTE of the first circuits 13, and a CTE of the second circuits 14.

In addition, the insulating layer 11 of the present embodiment includes the encapsulant 111, the two protective layers 112, and the protective strip 113, but the present disclosure is not limited thereto. For example, according to practical requirements, the protective strip 113 can be omitted, or a quantity of the two protective layers 112 can be adjusted, or the insulating layer 11 can be integrally formed as a single one-piece structure.

The sealing cover 4 includes a light-permeable sheet 41 and a frame 42 that is formed on the light-permeable sheet 41. In the present embodiment, the light-permeable sheet 41 is a filter glass, and the frame 42 is made of EMC, but the present disclosure is not limited thereto.

Specifically, the light-permeable sheet 41 has a light-permeable portion 411 and a ring-shaped portion 412 that surrounds the light-permeable portion 411, and the frame 42 is ring-shaped and is formed on the ring-shaped portion 412 of the light-permeable sheet 41. The sealing cover 4 is fixed (e.g., adhered) to the first surface 11a of the insulating layer 11 through the frame 42 so as to jointly define an enclosed space E. In other words, the frame 42 is not directly formed on the insulating layer 11. The sensor 2 and the metal wires 3 are located in the enclosed space E, and the light-permeable portion 411 faces toward the upper surface 2a of the sensor 2.

In summary, the sensor package 100 of the present embodiment can effectively reduce an overall size thereof through a top-bottom arrangement of the sensor 2 and the IC 12, and the insulating layer 11 of the sensing module 10 is used to be cooperated with the first circuits 13 and the second circuits 14 for replacing a conventional circuit board, thereby effectively preventing problems associated with the conventional circuit board.

### Second Embodiment

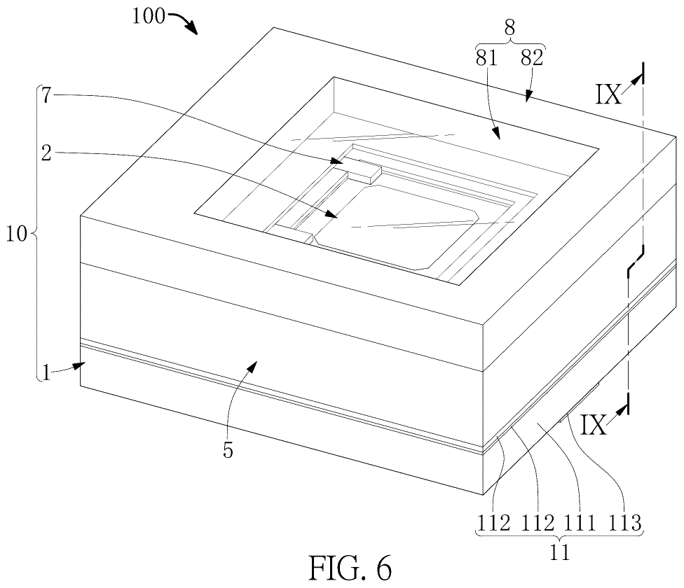

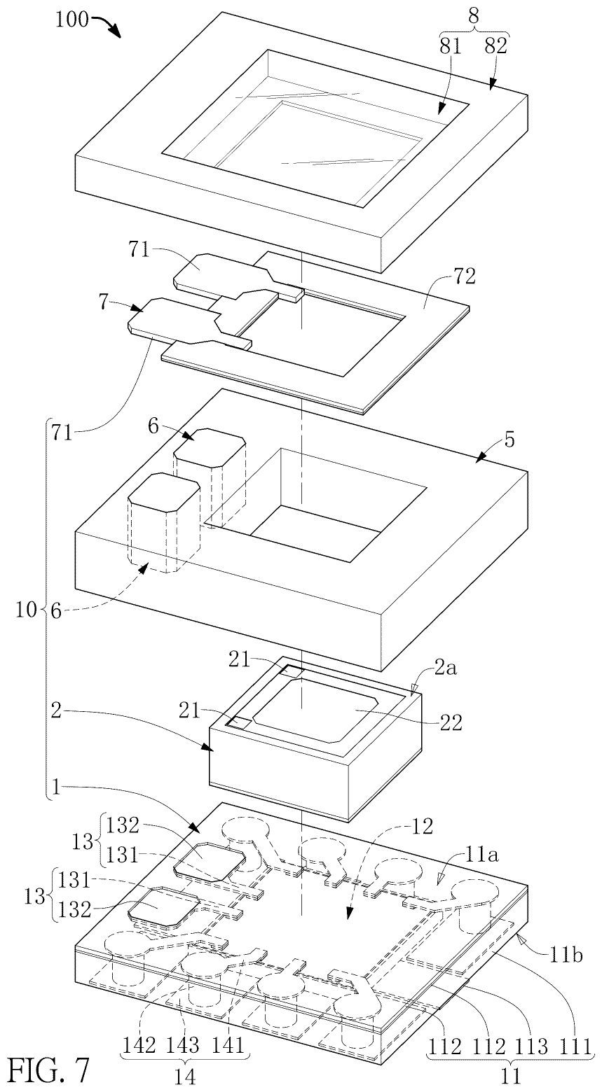

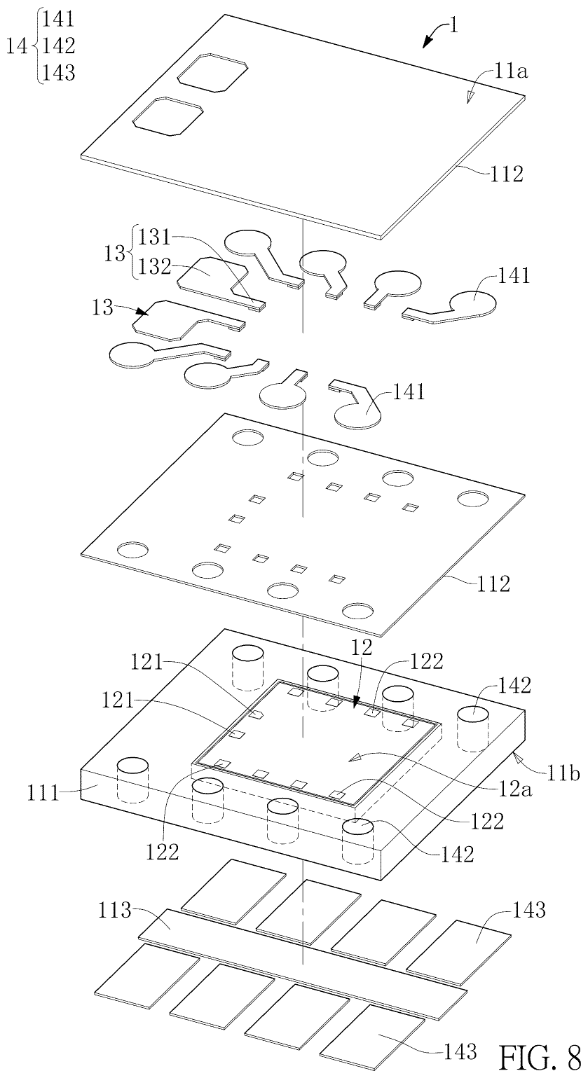

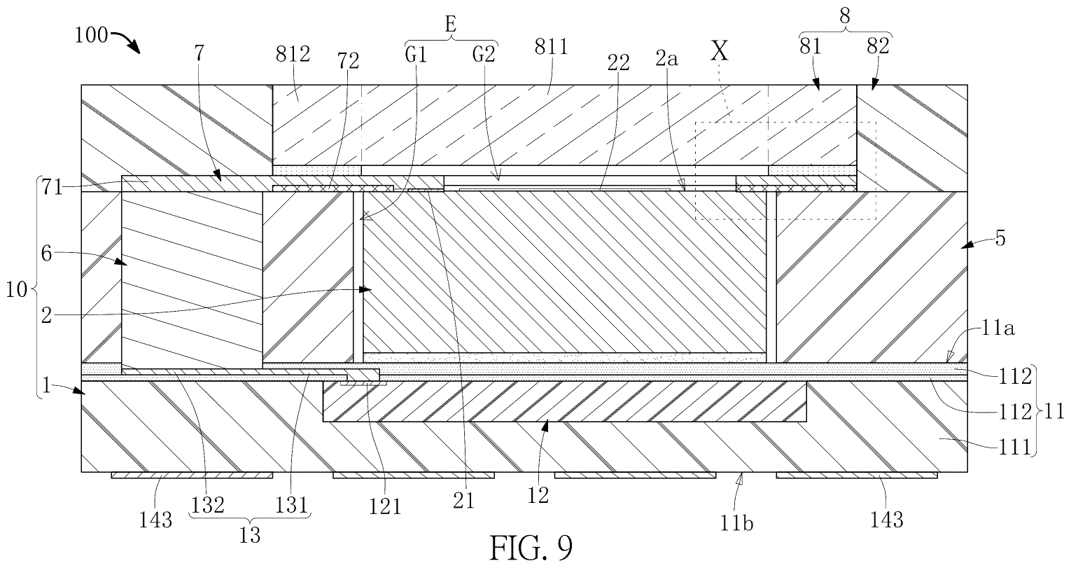

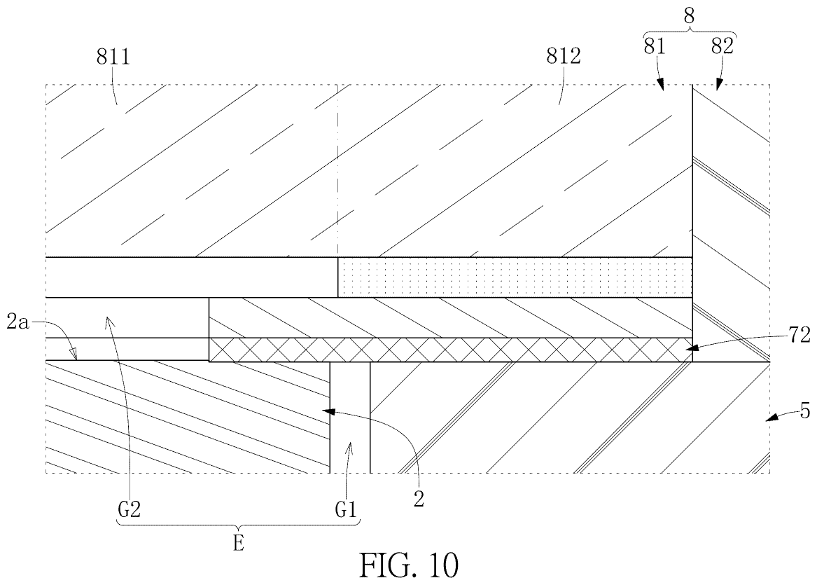

Referring to FIG. 6 to FIG. 10, a second embodiment of the present disclosure, which is similar to the first embodiment of the present disclosure, is provided. For the sake of brevity, descriptions of the same components in the first and second embodiments of the present disclosure (e.g., the sensing module 10) will be omitted herein, and the following description only discloses different features between the first and second embodiments.

In the present embodiment, the sensor package 100 includes a substrate 1, a sensor 2 disposed on the substrate 1, a frame 5 being ring-shaped and formed on the substrate 1, a plurality of metal pillars 6 embedded in the frame 5, a bridge layer 7 electrically coupled to the sensor 2 and the metal pillars 6, and a sealing layer 8 that covers the frame 5 and the bridge layer 7. It should be noted that the substrate 1 and the sensor 2 of the present embodiment can be jointly defined as a sensing module 10 and are identical to those of the first embodiment. Accordingly, the description of the substrate 1 and the sensor 2 of the present embodiment can be referred to in the first embodiment will not be described again below for the sake of brevity.

The frame 5 is formed on the first surface 11a of the insulating layer 11 and surrounds the sensor 2. In the present embodiment, the frame 5 is made of a molding compound (e.g., EMC or SMC), and the frame 5 is formed on the two protective layers 112 for being gaplessly connected to each other. The size of the frame 5 can be precisely controlled to enable a ring-shaped gap G1 between the frame 5 and the sensor 2 to be controlled within a range from 20 μm to 50 μm, thereby ensuring that the sensor 2 has a free space and is not easily affected by a thermal stress and an external force. Accordingly, the sensor 2 can have an accurate and stable sensing precision.

Moreover, a top side of the frame 5 is substantially coplanar with the upper surface 2a of the sensor 2, top sides of the metal pillars 6 embedded in the frame 5 are substantially coplanar with the top side of the frame 5, and bottom sides of the metal pillars 6 are respectively connected to the connection pads 132 of the sensing module 10, such that the metal pillars 6 are electrically coupled to the IC 12 through the first circuits 13. In the other word, top sides and bottom sides of the metal pillars 6 are individually exposed form the top side and the bottom side of the frame 5.

The bridge layer 7 includes a plurality of connection circuits 71 and a partition layer 72 that is disposed on the frame 5. One end of the connection circuits 71 is connected to the contacts 21 of the sensor 2, and another end of the connection circuits 71 is connected to the metal pillars 6, so that the sensor 2 can be electrically coupled to the IC 12 through the connection circuits 71, the metal pillars 6, and the first circuits 13, thereby shortening the electrical transmission path between the sensor 2 and the IC 12 and reducing generation of inductance and noise.

Moreover, the partition layer 72 is not only as an electrical insulator between the connection circuits 71 but also as an passivation layer on/below the connection circuits 71. In addition, the partition layer 72 is disposed on the top side of the frame 5 and the upper surface 2a of the sensor 2, and is not in contact with the sensing region 22 of the sensor 2. In other words, the partition layer 72 extends from the top side of the frame 5 to the upper surface 2a of the sensor 2 so as to enable the ring-shaped gap G1 to be enclosed. Accordingly, the ring-shaped gap G1 can be controlled within a very small range for allowing an infrared reflow soldering process to be implemented with no gas hole, and the ring-shaped gap G1 can be used to effectively block moisture and to protect the sensor 2.

It should be noted that the partition layer 72 in the present embodiment is a stacked dual-layer configuration, but the present disclosure is not limited thereto. For example, in other embodiments of the present disclosure not shown in the drawings, the partition layer 72 can be a single layer configuration according to practical requirements. In addition, the sensing module 10 of the present embodiment includes the substrate 1 and the sensor 2, and can further include components (e.g., the metal pillars 6 and the connection circuits 71) that are configured to be electrically coupled to the substrate 1 and the sensor 2.

The sealing layer 8 includes a light-permeable sheet 81 disposed on the bridge layer 7 and a sealing body 82 that is formed on the frame 5. In the present embodiment, the light-permeable sheet 81 is a filter glass, and the sealing body 82 is made of EMC, but the present disclosure is not limited thereto. The light-permeable sheet 81 has a light-permeable portion 811 and a ring-shaped portion 812 that surrounds the light-permeable portion 811. The ring-shaped portion 812 is disposed on (e.g., adhered to) the bridge layer 7 (e.g., the partition layer 72 and a part of each of the connection circuits 71), and the light-permeable portion 811 faces toward the sensing region 22 of the sensor 2.

Specifically, the light-permeable sheet 81 is spaced apart from the sensor 2 by a sensing gap G2 that is within a range from 20 μm to 50 μm, and the sensing gap G2 and the ring-shaped gap G1 are separated from each other through the partition layer 72. Accordingly, due to the configuration of the sensor package 100 provided by the present embodiment, the sensing gap G2 can be precisely controlled to ensure that the sensor 2 in operation has a uniform temperature and does not have crosstalk, such that the sensor 2 can have an accurate and stable sensing precision.

The sealing body 82 covers the bridge layer 7 and the ring-shaped portion 812 of the light-permeable sheet 81, and the sealing layer 7, the frame 5, and the substrate 1 jointly define an enclosed space E. The sensor 2 is located in the enclosed space E. In other words, the enclosed space E includes the sensing gap G2 and the ring-shaped gap G1. In the sensor package 100 of the present embodiment, the encapsulant 111, the frame 5, and the sealing body 82 are made of EMC, so that the sensor package 100 has an excellent sealing effect, and the sensor package 100 can effectively protect internal components thereof and accurately control the relative positions of components thereof.

### Beneficial Effects of the Embodiments

In conclusion, the sensor package and the sensing module provided by the present disclosure can effectively reduce an overall size thereof through a top-bottom arrangement of the sensor and the IC, and the insulating layer of the sensing module is used to be cooperated with the first circuits and the second circuits for replacing a conventional circuit board, thereby effectively preventing problems associated with the conventional circuit board.

Moreover, the sensing module provided by the present disclosure is a chip-scale configuration, thereby shortening the electrical transmission path between the sensor and the IC and reducing generation of inductance and noise. Moreover, the sensing module of the present disclosure is provided with the two protective layers for separating the first circuits and the second circuits from the IC and for effectively absorbing or releasing thermal stress that is generated by differences among a CTE of the sensor, a CTE of the first circuits, and a CTE of the second circuits.

In addition, due to the configuration of the sensor package provided by the present disclosure, the ring-shaped gap can be controlled within a very small range for allowing an infrared reflow soldering process to be implemented with no gas hole, and the ring-shaped gap can be used to effectively block moisture and to protect the sensor. Furthermore, the sensing gap can be precisely controlled to ensure that the sensor in operation has a uniform temperature and does not have crosstalk, such that the sensor can have an accurate and stable sensing precision.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package, comprising:
a substrate including:
an insulating layer having a first surface and a second surface that is opposite to the first surface;
an integrated circuit (IC) embedded in the insulating layer, wherein a top surface of the IC includes a plurality of first contacts and a plurality of second contacts;
a plurality of first circuits respectively connected to the first contacts, wherein a part of each of the first circuits is exposed from the first surface of the insulating layer and is defined as a connection pad; and
a plurality of second circuits respectively connected to the second contacts, wherein a part of each of the second circuits is exposed from the second surface of the insulating layer and is defined as a soldering pad;
a sensor disposed on the first surface of the insulating layer and electrically coupled to the connection pads of the first circuits; and
a sealing cover that is fixed to the first surface of the insulating layer so as to define an enclosed space, wherein the sensor is located in the enclosed space.

2. The sensor package according to claim 1, wherein each of the first circuits includes a first fan-out segment that is connected to the corresponding first contact and that is connected to the connection pad thereof, and each of the second circuits includes a second fan-out segment that is connected to the corresponding second contact and a conductive pillar that is connected to the second fan-out segment and that is connected to the soldering pad thereof, and wherein the first fan-out segments of the first circuits and the second fan-out segments and the conductive pillars of the second circuits are embedded in the insulating layer.

3. The sensor package according to claim 2, wherein the insulating layer includes:
an encapsulant, wherein the IC is embedded in the encapsulant, the top surface of the IC is exposed from the encapsulant, and the conductive pillars of the second circuits are embedded in the encapsulant; and
two protective layers covering the top surface of the IC, wherein the first fan-out segments of the first circuits and the second fan-out segments of the second circuits are embedded in the two protective layers.

4. The sensor package according to claim 3, wherein the soldering pads of the second circuits are arranged in two rows, and the insulating layer includes a protective strip disposed on the encapsulant and arranged between the two rows of the soldering pads.

5. The sensor package according to claim 4, wherein parts of the second fan-out segments of the second circuits are exposed from the two protective layers, individually connected to the corresponding conductive pillars and arranged in two rows.

6. The sensor package according to claim 1, wherein the sealing cover further includes:
a light-permeable sheet having a light-permeable portion and a ring-shaped portion that surrounds the light-permeable portion; and
a frame being ring-shaped and formed on the ring-shaped portion of the light-permeable sheet.

7. A sensor package, comprising:
a substrate including:
an insulating layer having a first surface and a second surface that is opposite to the first surface;
an integrated circuit (IC) embedded in the insulating layer, wherein a top surface of the IC includes a plurality of first contacts and a plurality of second contacts;
a plurality of first circuits respectively connected to the first contacts, wherein a part of each of the first circuits is exposed from the first surface of the insulating layer and is defined as a connection pad; and
a plurality of second circuits respectively connected to the second contacts, wherein a part of each of the second circuits is exposed from the second surface of the insulating layer and is defined as a soldering pad;
a sensor disposed on the first surface of the insulating layer, wherein an upper surface of the sensor includes a plurality of contacts;
a frame formed on the first surface of the insulating layer and surrounding the sensor;
a plurality of metal pillars respectively connected to the connection pads of the first circuit and embedded in the frame;
a bridge layer including a plurality of connection circuits and a partition layer that is disposed on the frame, wherein one end of the connection circuits is connected to the contacts of the sensor, and another end of the connection circuits is connected to the metal pillars; and
a sealing layer formed on the frame, wherein the sealing layer, the frame, and the substrate jointly define an enclosed space, and wherein the sensor is located in the enclosed space.

8. The sensor package according to claim 7, wherein the sealing layer including:
a light-permeable sheet disposed on the bridge layer, wherein the light-permeable layer has a light-permeable portion and a ring-shaped portion that surrounds the light-permeable portion; and
a sealing body formed on the frame and covering the bridge layer.

9. The sensor package according to claim 8, wherein the light-permeable sheet is spaced apart from the sensor by a sensing gap that is within a range from 20 μm to 50 μm, and the frame is spaced apart from the sensor by a ring-shaped gap that is within a range from 20 μm to 50 μm.

10. The sensor package according to claim 9, wherein the partition layer separates the sensing gap and the ring-shaped gap by extending onto the upper surface of the sensor.

11. The sensor package according to claim 7, wherein the partition layer is disposed between the connection circuits and extends from the top side of the frame to the upper surface of the sensor.

12. The sensor package according to claim 7, wherein each of the first circuits includes a first fan-out segment that is connected to the corresponding first contact and that is connected to the connection pad thereof, and each of the second circuits includes a second fan-out segment that is connected to the corresponding second contact and a conductive pillar that is connected to the second fan-out segment and that is connected to the soldering pad thereof, and wherein the first fan-out segments of the first circuits and the second fan-out segments and the conductive pillars of the second circuits are embedded in the insulating layer.

13. The sensor package according to claim 12, wherein the insulating layer includes:
an encapsulant, wherein the IC is embedded in the encapsulant, the top surface of the IC is exposed from the encapsulant, and the conductive pillars of the second circuits are embedded in the encapsulant; and
two protective layers covering the top surface of the IC, wherein the first fan-out segments of the first circuits and the second fan-out segments of the second circuits are embedded in the two protective layers.

14. The sensor package according to claim 13, wherein the soldering pads of the second circuits are arranged in two rows, and the insulating layer includes a protective strip disposed on the encapsulant and arranged between the two rows of the soldering pads.

15. The sensor package according to claim 8, wherein any one of the frame and the sealing body is an epoxy molding compound (EMC) or a silicone molding compound (SMC).

16. A sensing module of a sensor package, comprising:
a substrate including:
an insulating layer having a first surface and a second surface that is opposite to the first surface;
an integrated circuit (IC) embedded in the insulating layer, wherein a top surface of the IC includes a plurality of first contacts and a plurality of second contacts;
a plurality of first circuits respectively connected to the first contacts, wherein a part of each of the first circuits is exposed from the first surface of the insulating layer and is defined as a connection pad; and
a plurality of second circuits respectively connected to the second contacts, wherein a part of each of the second circuits is exposed from the second surface of the insulating layer and is defined as a soldering pad; and
a sensor disposed on the first surface of the insulating layer and electrically coupled to the first circuits.

17. The sensing module according to claim 16, wherein each of the first circuits includes a first fan-out segment that is connected to the corresponding first contact and that is connected to the connection pad thereof, and each of the second circuits includes a second fan-out segment that is connected to the corresponding second contact and a conductive pillar that is connected to the second fan-out segment and that is connected to the soldering pad thereof, and wherein the first fan-out segments of the first circuits and the second fan-out segments and the conductive pillars of the second circuits are embedded in the insulating layer.

18. The sensing module according to claim 17, wherein the insulating layer includes:
an encapsulant, wherein the IC is embedded in the encapsulant, the top surface of the IC is exposed from the encapsulant, and the conductive pillars of the second circuits are embedded in the encapsulant; and
two protective layers covering the top surface of the IC, wherein the first fan-out segments of the first circuits and the second fan-out segments of the second circuits are embedded in the two protective layers.

19. The sensing module according to claim 18, wherein the soldering pads of the second circuits are arranged in two rows, and the insulating layer includes a protective strip disposed on the encapsulant and arranged between the two rows of the soldering pads.

20. The sensor package according to claim 19, wherein parts of the second fan-out segments of the second circuits are exposed from the two protective layers, individually connected to the corresponding conductive pillars and arranged in two rows.
